(19) United States
(12) Patent Application Publication
(10) Pub. No.: US 2008/0296611 A1
(43) Pub. Date: Dec. 4, 2008

(54) SEMICONDUCTOR DEVICE AND METHOD FOR MANUFACTURING SAME

(75) Inventors: Motoshige Kobayashi, Kanagawa-ken (JP); Hideki Nozaki, Kanagawa-ken (JP); Masanobu Tsuchitani, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/871,541

(22) Filed: Oct. 12, 2007

(30) Foreign Application Priority Data
Oct. 13, 2006 (JP) 2006-280786

(51) Int. Cl. H01L 29/772; H01L 21/332

(52) U.S. Cl. 257/133; 438/138; 257/E29.242

(57) ABSTRACT

A semiconductor device includes: a semiconductor layer having a first major surface, a second major surface provided on opposite side of the first major surface, and a channel formation region provided in a surface portion on the first major surface side; a first main electrode provided inside a dicing street on the first major surface of the semiconductor layer; a second main electrode provided inside a dicing street on the second major surface of the semiconductor layer; and a control electrode opposed to the channel formation region across an insulating film.

### CROSS-REFERENCE TO RELATED APPLICATIONS

This application is based upon and claims the benefit of priority from the prior Japanese Patent Application No. 2006-280786, filed on Oct. 13, 2006; the entire contents of which are incorporated herein by reference.

### BACKGROUND OF THE INVENTION

1. Field of the Invention

This invention relates to a semiconductor device and a method for manufacturing the same.

2. Background Art

Vertical semiconductor devices such as vertical MOSFET (metal-oxide-semiconductor field effect transistor) and IGBT (insulated gate bipolar transistor) are provided with electrodes also on the backside (see, e.g., JP-A 2006-059876(Kokai)).

The backside electrode is often mounted on the mounting surface with solder. The backside electrode is formed relatively thick, and made of metal softer than semiconductor (such as silicon). For this reason, when the backside electrode is cut with a blade during dicing, the blade is clogged, and chipping (chipping at the edge of the dicing street) is likely to occur on the backside. Furthermore, when a metal is formed entirely on the wafer backside, warpage occurs particularly in the case of a thin wafer, causing difficulty in transporting it in the subsequent steps.

### SUMMARY OF THE INVENTION

According to an aspect of the invention, there is provided a semiconductor device including: a semiconductor layer including a first major surface, a second major surface provided on opposite side of the first major surface, and a channel formation region provided in a surface portion on the first major surface side; a first main electrode provided inside a dicing street on the first major surface of the semiconductor layer; a second main electrode provided inside a dicing street on the second major surface of the semiconductor layer; and a control electrode opposed to the channel formation region across an insulating film.

According to another aspect of the invention, there is provided a method for manufacturing a semiconductor device, including: forming a channel formation region in a surface portion on a first major surface side of a semiconductor layer; forming a control electrode opposed to the channel formation region across an insulating film; forming a first main electrode on the first major surface of the semiconductor layer; and forming a second main electrode in a region surrounded by a dicing street on a second major surface provided on opposite side of the first major surface of the semiconductor layer.

### BRIEF DESCRIPTION OF THE DRAWINGS

FIG. 1 is a schematic plan view showing the backside of a semiconductor device according to the embodiment of the Invention.

FIG. 2 is a schematic cross-sectional view of the semiconductor device.

FIG. 3 is a schematic view illustrating the cross section of the main part of an IGBT having a planar gate structure.

FIG. 4 is a schematic view illustrating the cross section of the main part of an IGBT having a trench gate structure.

FIGS. 5A to 5F are process cross-sectional views showing the process of forming the second main electrode 2 and the dicing process for the semiconductor device according to the embodiment of the invention.

FIGS. 6A to 6G area process cross-sectional views in which the second main electrode is formed by plating for the semiconductor device according to the embodiment of the invention.

FIGS. 7A to 7E are process cross-sectional views in which the same plating layer as the second main electrode is formed also on the surface of the first main electrode when the second main electrode is formed by plating for the semiconductor device according to the embodiment of the invention.

FIG. 8 is a graph showing the transition of wafer warpage after individual processes performed on the backside of semiconductor wafers.

### DETAILED DESCRIPTION OF THE INVENTION

An embodiment of the invention will now be described with reference to the drawings.

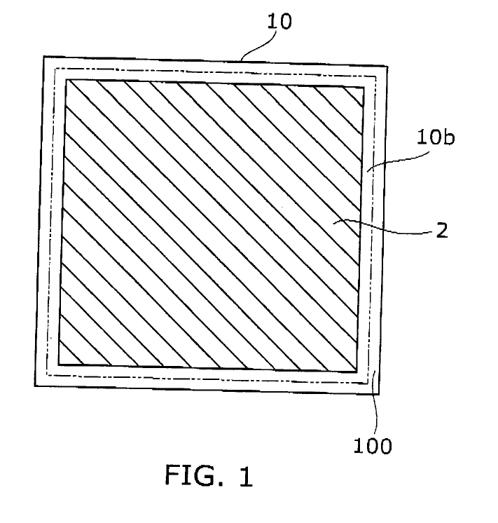

FIG. 1 is a schematic plan view showing the backside of a semiconductor device according to the embodiment of the invention.

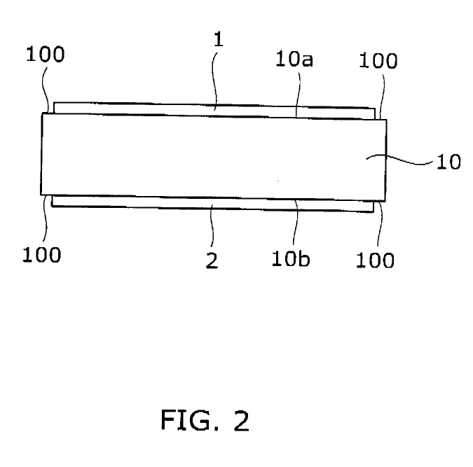

FIG. 2 is a schematic cross-sectional view of the semiconductor device.

This embodiment is described with reference to an insulated gate bipolar transistor (IGBT), taken as an example of the semiconductor device.

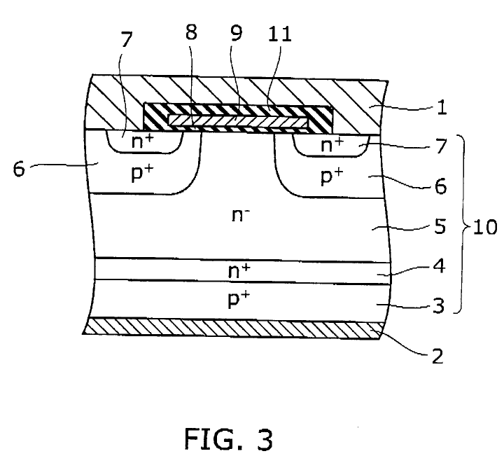

FIG. 3 is a schematic view illustrating the cross section of the main part of an IGBT having a planar gate structure.

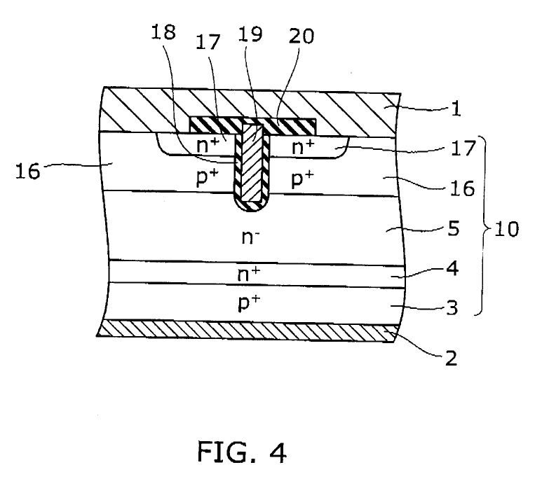

FIG. 4 is a schematic view illustrating the cross section of the main part of an IGBT having a trench gate structure.

As shown in FIG. 2, the semiconductor device according to this embodiment comprises a semiconductor layer 10 with an active region such as a channel formation region formed therein, a first main electrode 1 provided on a first major surface 10a of the semiconductor layer 10, and a second main electrode 2 provided on a second major surface 10b, which is a surface on the opposite side of the first major surface 10a.

As shown in FIG. 1, a dicing street 100 is formed on the rim of the backside (second major surface 10b) of the semiconductor device. Likewise, although not shown, a dicing street 100 is formed also on the rim of the frontside (first major surface 10a) of the semiconductor device. The dicing street 100 is a boundary formed between individual semiconductor devices (semiconductor chips) on a wafer before the semiconductor devices (semiconductor chips) are separately cut out. A dicing blade cuts the wafer along the dicing street 100.

The width of the dicing street on the wafer is e.g. 70 to 100 μm, and the width of the dicing street 100 left on the rim of each diced semiconductor device (semiconductor chip) is e.g. substantially 20 to 30 μm.

As shown in FIG. 1, the second main electrode 2 is formed inside the dicing street 100 on the second major surface 10b of the semiconductor layer 10. Likewise, the first main electrode 1 is also formed inside the dicing street 100 on the first major surface 10a of the semiconductor layer 10.

The channel formation region and the control electrode opposed to the channel formation region across an insulating film are formed in the surface portion on the first major surface 10a side of the semiconductor layer 10.

The IGBT having a planar gate structure shown in FIG. 3 includes an n⁺-type buffer layer 4 and an n⁻-type base layer 5 sequentially on a p⁺-type silicon substrate (collector layer) 3. A p⁺-type base region 6 is selectively provided in the surface portion of the n⁻-type base layer 5, and an n⁺-type emitter region 7 is selectively provided in the surface of the base region 6.

A control electrode 9 is provided via an insulating film 8 on the surface extending from a portion of the emitter region 7 through the base region 6 to the n⁻-type base layer 5 (the surface corresponding to the first major surface of the semiconductor layer 10). The surface portion opposed to the control electrode 9 across the insulating film 8 functions as a channel formation region.

The control electrode 9 is covered with an interlayer insulating film 11, and the first main electrode 1 is provided in contact with the emitter region 7 so as to cover the Interlayer insulating film 11.

The second main electrode 2 is provided on the backside of the collector layer 3, which corresponds to the second major surface of the semiconductor layer 10.

The IGBT having a trench gate structure shown in FIG. 4 includes an n⁺-type buffer layer 4 and an n⁻-type base layer 5 sequentially on a p⁺-type silicon substrate (collector layer) 3. A p⁺-type base region 16 is provided in the surface portion of the n⁻-type base layer 5, and an n⁺-type emitter region 17 is selectively provided in the surface of the base region 16.

From the surface of the emitter region 17 corresponding to the first major surface of the semiconductor layer 10, a trench is formed through the emitter region 17 and the base region 16 to the n⁻-type base layer 5. The trench is filled in with a control electrode 19 via an insulating film 18. The portion opposed to the control electrode 19 across the insulating film 18 functions as a channel formation region.

The first main electrode 1 is provided on the surface of the emitter region 17 and the base region 16 (the surface corresponding to the first major surface of the semiconductor layer 10). An Interlayer insulating film 20 is interposed between the first main electrode 1 and the control electrode 19.

The second main electrode 2 is provided on the backside of the collector layer 3, which corresponds to the second major surface of the semiconductor layer 10.

In the IGBT described above, upon application of a desired control voltage (gate voltage) to the control electrode 9, 19, an n-channel is formed in the channel formation region opposed to the control electrode 9, 19 across the insulating film 8, 18, and the path between the first main electrode 1 and the second main electrode 2 (emitter-collector path) is turned into the ON state. In an IGBT, electrons and holes are injected from the emitter and the collector, respectively, and carriers are accumulated in the n⁻-type base layer 5, thereby causing conductivity modulation. Hence the ON resistance can be made lower in the IGBT than in the vertical MOSFET (metal-oxide-semiconductor field effect transistor).

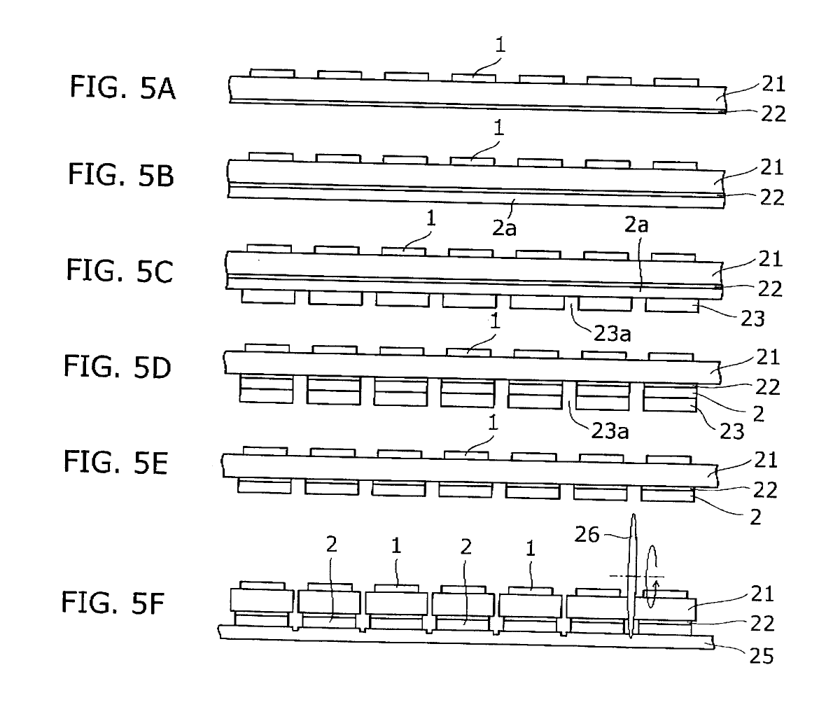

FIGS. 5A to 5F are process cross-sectional views showing the process of forming the second main electrode 2 and the dicing process for the semiconductor device according to the embodiment of the invention.

The structure shown in FIG. 3 or 4 other than the second main electrode 2 is formed on a semiconductor wafer 21. Then, as shown in FIG. 5A, a contact layer 22 is formed entirely on the backside (second major surface) of the semiconductor wafer 21. The contact layer 22 is illustratively formed from aluminum by evaporation and has a thickness of 200 nm. For providing ohmic contact with the semiconductor layer, the contact layer 22 is sintered for ten to several ten minutes in nitrogen gas at 400 to 500° C., for example.

Next, as shown in FIG. 5B, a metal layer 2a is formed entirely on the contact layer 22 by sputtering, for example. The metal layer 2a is made of a material having good wettability with solder, and illustratively composed of a Ti layer, Ni layer, and Au layer sequentially laminated from the contact layer 22 side. For example, the Ti layer has a thickness of 200 nm, the Ni layer has a thickness of 700 nm, and the Au layer has a thickness of 100 nm.

Next, a resist film is formed on the entire surface of the metal layer 2a. Then, as shown in FIG. 5C, the resist film is selectively removed by photolithography and etching. Thus the resist film is patterned to form a mask 23. The mask 23 has openings 23a at positions corresponding to the dicing lines in the semiconductor wafer 21. A double-sided exposure system can be illustratively used in this photolithography process.

Next, as shown in FIG. 5D, the mask 23 is used to etch the metal layer 2a with aqua regia, for example. Then, as shown in FIG. 5E, the mask 23 is peeled off. Thus the second main electrodes 2 being patterned are formed on the backside (second major surface) of the semiconductor wafer 21.

The metal layer 2a is selectively etched away only in the portion exposed in the openings 23a of the mask 23. Hence the second main electrode 2 is not formed in the portion corresponding to the lattice-shaped dicing streets, but is formed in the region surrounded by the dicing streets, the region being formed like an island on the backside of the semiconductor wafer 21.

In the example shown in FIG. 5, the contact layer 22 is not etched, but is left entirely on the backside of the semiconductor wafer 21. However, like the metal layer 2a, the contact layer 22 may be also etched away in the portion exposed in the openings 23a of the mask 23.

After the second main electrodes 2 are formed, as shown in FIG. 5F, with the second main electrodes 2 being stuck on a dicing tape 25, the semiconductor wafer 21 is cut along the dicing street using a blade 26 and separated into individual semiconductor devices (semiconductor chips). The blade 26 has an edge width of e.g. 30 to 40 μm, and the dicing street has a width of e.g. 70 to 100 μm.

As described above, the second main electrode 2 is patterned so as not to be provided at the position corresponding to the dicing street. Hence, during dicing, the blade 26 escapes cutting the second main electrode 2. Thus clogging of the blade 26 and chipping (chipping at the edge of the dicing street) caused thereby can be prevented.

The contact layer 22 is provided in order to make ohmic contact with the semiconductor layer, and is thinner than the second main electrode 2. Hence, even if the blade 26 cuts the contact layer 22 residing on the dicing street, clogging of the blade 26 and chipping caused thereby are less likely to occur.

The first main electrodes 1 are formed in a pattern partitioned into chips on the wafer, and hence do not reside on the dicing street.

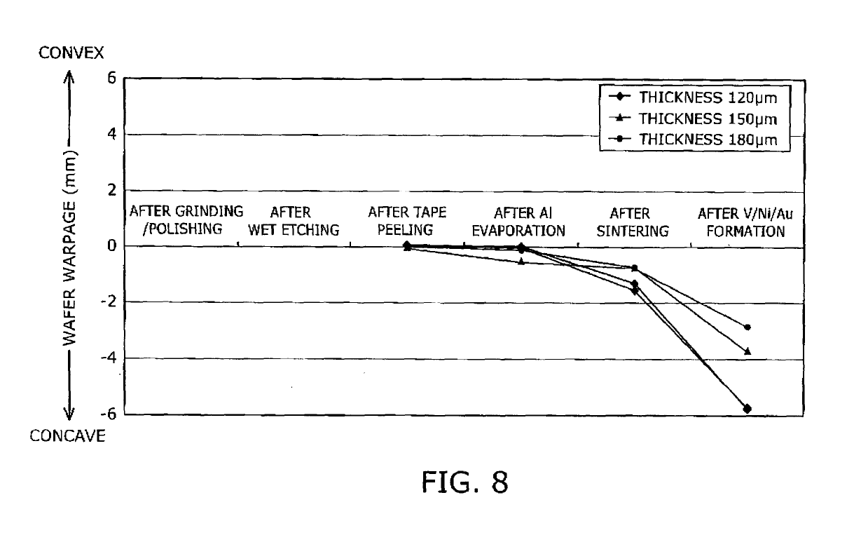

FIG. 8 is a graph showing the transition of wafer warpage (in mm) after individual processes (after grinding/polishing, after wet etching, after tape peeling, after evaporation of aluminum as a contact layer, after sintering, and after forming V/Ni/Au as a second main electrode) performed on the backside of semiconductor wafers having a thickness of 120 μm, 150 μm, and 180 μm.

The aluminum film and the V/Ni/Au film are not patterned as in this embodiment described above, but are formed entirely on the backside of the semiconductor wafer.

The vertical axis upward of “0” represents warpage (in mm) for a convexly warped semiconductor wafer with the backside up. The vertical axis downward of “0” represents warpage (in mm) for a concavely warped semiconductor wafer with the backside up.

From the result of FIG. 8, when a metal film is formed entirely on the backside of the semiconductor wafer, large warpage occurs in the semiconductor wafer by the stress of the film, particularly by the stress of the V/Ni/Au film serving as a second main electrode, which is thicker than the aluminum film for ohmic contact.

In this embodiment, the second main electrodes formed on the backside (second major surface) of the semiconductor wafer are patterned like islands. Therefore the film stress can be reduced relative to the second main electrode formed entirely on the backside, and wafer warpage can be restrained.

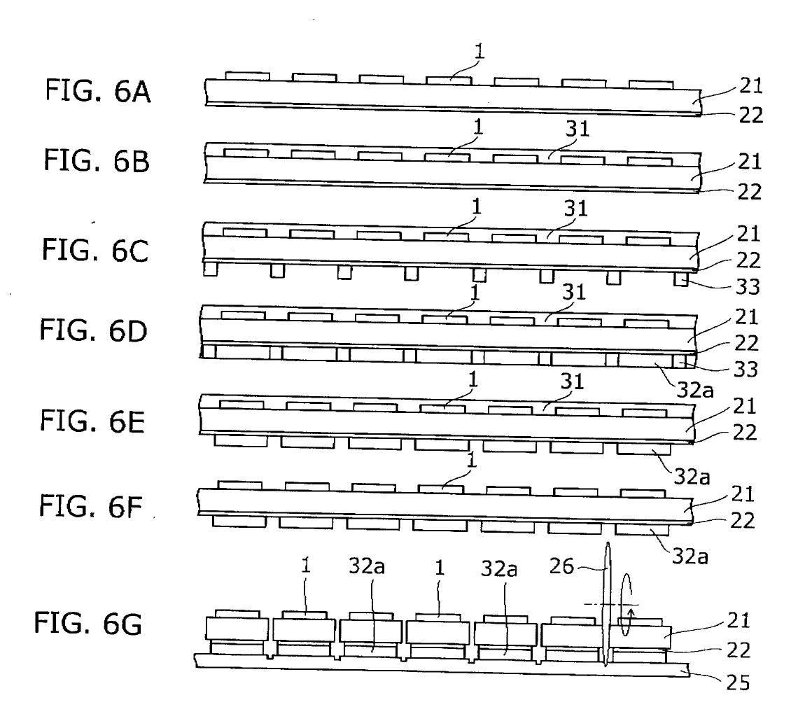

FIGS. 6A to 6G are process cross-sectional views in which the second main electrode is formed by plating.

An IGBT, for example, other than the second main electrode is formed on a semiconductor wafer 21. Then, as shown in FIG. 6A, a contact layer 22 is formed entirely on the backside (second major surface) of the semiconductor wafer 21. The contact layer 22 is illustratively formed from aluminum by evaporation and has a thickness of e.g. 200 nm. For providing ohmic contact with the semiconductor layer, the contact layer 22 is sintered for ten to several ten minutes in nitrogen gas at 400 to 500° C., for example.

Next, as shown in FIG. 6B, a protective tape 31 is stuck on the frontside (first major surface) of the semiconductor wafer 21 so as to cover the first main electrodes 1. Here, instead of the protective tape 31, a resist film may be formed.

Next, as shown in FIG. 6C, a plating resist 33 is selectively formed on the surface of the contact layer 22. The plating resist 33 is provided at positions corresponding to the dicing lines in the semiconductor wafer 21. A double-sided exposure system can be illustratively used in this exposure process for the plating resist.

Next, as shown in FIG. 6D, the plating resist 33 is used as a mask to perform electroplating, and second main electrodes 32a are deposited on the surface of the contact layer 22. The second main electrode 32a is illustratively composed of a Ni layer and Au layer sequentially formed from the contact layer 22 side. For example, the Ni layer has a thickness of 0.5 to 10 μm. The Au layer serving for oxidation protection of the surface is thinner than the Ni layer and has a thickness of e.g. 100 nm. Instead of the Ni/Au layer, the second main electrode 32a may be made of copper with a thickness of e.g. 0.5 to 10 μm formed by electroplating.

During plating of the second main electrode 32a, the first main electrode 1 on the frontside is covered with the protective tape 31. Hence no plating layer is deposited on the surface of the first main electrode 1.

Then the plating resist 33 is peeled off. Thus, as shown in FIG. 6E, the second main electrodes 32a being patterned are formed on the backside (second major surface) of the semiconductor wafer 21.

The plating resist 33 is provided at positions corresponding to the lattice-shaped dicing streets. Hence the second main electrode 32a is not formed in the portion corresponding to the dicing streets, but is formed in the region surrounded by the dicing streets, the region being formed like an island on the backside of the semiconductor wafer 21. Therefore the film stress can be reduced relative to the second main electrode formed entirely on the backside, and wafer warpage can be restrained.

The protective tape 31 stuck on the frontside is peeled off as shown in FIG. 6F after plating of the second main electrode 32a.

Next, as shown in FIG. 6G, with the second main electrodes 32a being stuck on a dicing tape 25, the semiconductor wafer 21 is cut along the dicing street using a blade 26 and separated into individual semiconductor devices (semiconductor chips). The blade 26 has an edge width of e.g. 30 to 40 μm, and the dicing street has a width of e.g. 70 to 100 μm.

As described above, the second main electrode 32a is patterned so as not to be provided at the position corresponding to the dicing street. Hence, during dicing, the blade 26 escapes cutting the second main electrode 32a. Thus clogging of the blade 26 and chipping (chipping at the edge of the dicing street) caused thereby can be prevented.

In the example described with reference to FIG. 6, if the frontside is not protected with the tape 31 or resist before plating, a plating layer similar to the second main electrode 32a can be formed also on the first main electrode 1.

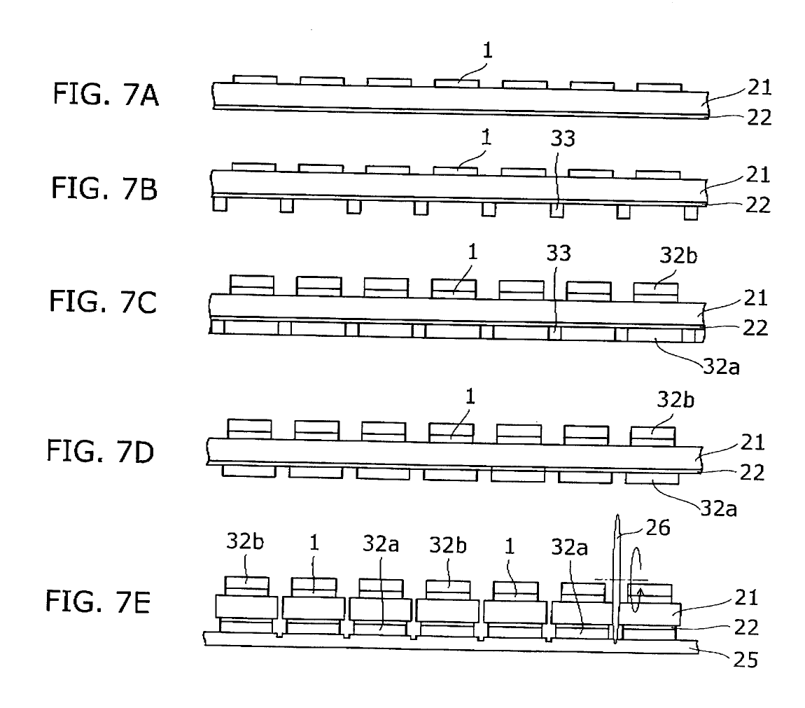

FIGS. 7A to 7E are process cross-sectional views in which the same plating layer as the second main electrode is formed also on the surface of the first main electrode when the second main electrode is formed by plating.

An IGBT, for example, other than the second main electrode is formed on a semiconductor wafer 21. Then, as shown in FIG. 7A, a contact layer 22 is formed entirely on the backside (second major surface) of the semiconductor wafer 21. The contact layer 22 is illustratively formed from aluminum by evaporation and has a thickness of e.g. 200 nm. For providing ohmic contact with the semiconductor layer, the contact layer 22 is sintered for ten to several ten minutes in nitrogen gas at 400 to 500° C., for example.

Next, as shown in FIG. 7B, a plating resist 33 is selectively formed on the surface of the contact layer 22. The plating resist 33 is provided at positions corresponding to the dicing lines in the semiconductor wafer 21.

Next, as shown in FIG. 7C, the plating resist 33 is used as a mask to perform electroplating, and second main electrodes 32a are deposited on the surface of the contact layer 22. The second main electrode 32a is illustratively composed of a Ni layer and Au layer sequentially formed from the contact layer 22 side. For example, the Ni layer has a thickness of 0.5 to 10 μm. The Au layer serving for oxidation protection of the surface is thinner than the Ni layer and has a thickness of e.g. 100 nm. Instead of the Ni/Au layer, the second main electrode 32a may be made of copper with a thickness of e.g. 0.5 to 10 μm formed by electroplating.

At this time, because the first main electrode 1 is not covered with a protective tape or resist, a plating layer 32b having the same material and thickness as the second main electrode 32a is deposited also on the surface of the first main electrode 1. Here, on the first major surface of the semiconductor wafer 21, the portion outside the first main electrode 1 is made of silicon or oxide film. Hence the plating layer 32b is deposited only on the surface of the first main electrode 1.

Then the plating resist 33 is peeled off. Thus, as shown in FIG. 7D, the second main electrodes 32a being patterned are formed on the backside (second major surface) of the semiconductor wafer 21.

The plating resist 33 is provided at positions corresponding to the lattice-shaped dicing streets. Hence the second main electrode 32a is not formed in the portion corresponding to the dicing streets, but is formed in the region surrounded by the dicing streets, the region being formed like an island on the backside of the semiconductor wafer 21. Therefore the film stress can be reduced relative to the second main electrode formed entirely on the backside, and wafer warpage can be restrained.

Furthermore, the plating layer 32b having the same material and thickness as the second main electrode 32a is deposited also on the surface of the first main electrode 1. Hence the film stress of the metal layer is made uniform both on the frontside and backside of the semiconductor wafer 21, achieving a significant effect of restraining warpage.

Next, as shown in FIG. 7E, with the second main electrodes 32a being stuck on a dicing tape 25, the semiconductor wafer 21 is cut along the dicing street using a blade 26 and separated into individual semiconductor devices (semiconductor chips). The blade 26 has an edge width of e.g. 30 to 40 μm, and the dicing street has a width of e.g. 70 to 100 μm.

The second main electrode 32a is patterned so as not to be provided at the position corresponding to the dicing street. Hence, during dicing, the blade 26 escapes cutting the second main electrode 32a. Thus clogging of the blade 26 and chipping (chipping at the edge of the dicing street) caused thereby can be prevented.

The embodiment of the invention has been described with reference to examples. However, the invention is not limited thereto, but can be variously modified within the spirit of the invention.

The invention is applicable to vertical semiconductor devices with a first main electrode provided on one major surface of a semiconductor layer and a second main electrode provided on the other major surface thereof. Besides IGBT, the invention is applicable to thyristors, GTO (gate turn-off) thyristors, and MOSFET, for example.

1. A semiconductor device comprising;
a semiconductor layer including a first major surface, a second major surface provided on opposite side of the first major surface, and a channel formation region provided in a surface portion on the first major surface side;
a first main electrode provided inside a dicing street on the first major surface of the semiconductor layer;
a second main electrode provided inside a dicing street on the second major surface of the semiconductor layer; and
a control electrode opposed to the channel formation region across an insulating film.

2. The semiconductor device according to claim 1, wherein a metal layer having substantially the same material and thickness as the second main electrode is provided on a surface of the first main electrode.

3. The semiconductor device according to claim 1, wherein a contact layer forming ohmic contact with the semiconductor layer is provided between the second major surface of the semiconductor layer and the second main electrode.

4. The semiconductor device according to claim 1, wherein the semiconductor layer includes;
a collector layer of a first conductivity type semiconductor,
a buffer layer of a second conductivity type semiconductor provided on the collector layer,
a base layer of the second conductivity type semiconductor provided on the buffer layer,
a base region of the first conductivity type semiconductor provided on a surface of the base layer, and
an emitter region of the second conductivity type semiconductor selectively provided on a surface of the base region, the first main electrode is in contact with the emitter region and the base region, and
the second main electrode is in contact with the collector layer.

5. The semiconductor device according to claim 4, wherein the control electrode is opposed to a portion across the insulating layer, the portion extending from a part of the emitter region through the base region to the base layer on the major surface of the semiconductor layer.

6. The semiconductor device according to claim 4, wherein a trench penetrating from a surface of the emitter region through the emitter region and the base region to the base layer is provided, and the control electrode is provided in the trench across the insulating film.

7. A method for manufacturing a semiconductor device, comprising:
forming a channel formation region in a surface portion on a first major surface side of a semiconductor layer;
forming a control electrode opposed to the channel formation region across an insulating film;
forming a first main electrode on the first major surface of the semiconductor layer; and
forming a second main electrode in a region surrounded by a dicing street on a second major surface provided on opposite side of the first major surface of the semiconductor layer.

8. The method for manufacturing a semiconductor device according to claim 7, wherein the second main electrode is deposited by plating.

9. The method for manufacturing a semiconductor device according to claim 8, wherein the second main electrode is deposited by the plating using a plating resist provided at positions corresponding to the dicing street on the second major surface of the semiconductor layer as a mask.

10. The method for manufacturing a semiconductor device according to claim 8, wherein the second main electrode is deposited by the plating while the first main electrode is covered with a protective tape.

11. The method for manufacturing a semiconductor device according to claim 8, wherein the second main electrode is deposited by the plating while the first main electrode is covered with a resist film.

12. The method for manufacturing a semiconductor device according to claim 8, wherein a plating layer is deposited also on a surface of the first main electrode simultaneously when the second main electrode is deposited by plating.

13. The method for manufacturing a semiconductor device according to claim 8, wherein the second main electrode deposited by the plating includes at least one selected from Ni, Au and Cu.

14. The method for manufacturing a semiconductor device according to claim 7, wherein the second main electrode is formed by sputtering.

15. The method for manufacturing a semiconductor device according to claim 14, wherein the second main electrode formed by the sputtering includes at least one selected from Ti, Ni and Au.

16. The method for manufacturing a semiconductor device according to claim 7, wherein the method further includes forming a contact layer on the second major surface before the forming the second main electrode.

17. The method for manufacturing a semiconductor device according to claim 16, wherein the method further includes sintering the contact layer in nitrogen gas after the forming the contact layer.

18. The method for manufacturing a semiconductor device according to claim 7, wherein
the forming the channel formation region,
the forming the control electrode,
the forming the first main electrode, and
the forming the second main electrode are performed before a semiconductor wafer is cut along the dicing street.

19. The method for manufacturing a semiconductor device according to claim 18, further comprising cutting the semiconductor wafer along the dicing street using a blade while the second main electrode is stuck on a dicing tape.

20. The method for manufacturing a semiconductor device according to claim 19, wherein a width of the dicing street of the semiconductor wafer is larger than an edge width of the blade.
